(19) United States
(12) Patent Application Publication
(10) Pub. No.: US 2008/0174021 A1
(43) Pub. Date: Jul. 24, 2008

(54) SEMICONDUCTOR DEVICES HAVING METAL INTERCONNECTIONS, SEMICONDUCTOR CLUSTER TOOLS USED IN FABRICATION THEREOF AND METHODS OF FABRICATING THE SAME

(75) Inventors: Kyung-In Choi, Seoul (KR); Hyun-Bae Lee, Seoul (KR); Gil-Heyun Choi, Seoul (KR); Jong-Myeong Lee, Gyeonggi-do (KR); Jong-Won Hong, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/014,458

(22) Filed: Jan. 15, 2008

(30) Foreign Application Priority Data
Jan. 18, 2007 (KR) 10-2007-0005732
Apr. 24, 2007 (KR) 10-2007-00039874

(51) Int. Cl. H01L 23/52; H01L 21/4763; C23C 16/00

(52) U.S. Cl. 257/751; 438/643; 118/719; 257/E21.495; 257/E23.141

(57) ABSTRACT

A method of fabricating a semiconductor device is provided. The method includes providing a semiconductor substrate having a conductive pattern and forming an insulating layer on the conductive pattern and the semiconductor substrate. The insulating layer is patterned to form an opening which exposes a portion of the conductive pattern. A preliminary diffusion barrier layer is formed on an inner wall of the opening and a top surface of the insulating layer. Oxygen atoms are supplied onto the preliminary diffusion barrier layer to form a first diffusion barrier layer. A metal layer is formed on the first diffusion barrier layer. The metal layer is formed to fill the opening surrounded by the first diffusion barrier layer. A semiconductor device fabricated by the method and a semiconductor cluster tool used in fabrication of the semiconductor device are also provided.

### CROSS-REFERENCE TO RELATED APPLICATIONS

This U.S. non-provisional patent application claims priority under 35 U.S.C §119 of Korean Patent Application Nos. 2007-5732 and 2007-39874, filed on Jan. 18, 2007 and Apr. 24, 2007, respectively, the contents of which are incorporated herein by reference in their entirety.

### BACKGROUND

The present invention relates generally to semiconductor devices, and, more particularly, to tools and methods of fabricating semiconductor devices.

As semiconductor devices become more highly integrated, a width and a thickness of metal interconnections have been gradually reduced to increase the electrical resistance of the metal interconnections. Thus, an aluminum layer widely used as a metal interconnection layer has been replaced with a copper layer having a low resistivity. However, when the copper layer is used in formation of topmost interconnections such as bonding pads, the copper layer may be easily oxidized. Thus, the aluminum layer is still used in formation of the topmost interconnections which are located over the copper interconnections. In this case, the aluminum interconnection may be in direct contact with the copper interconnection in a contact region such as a contact hole, and copper atoms in the copper interconnections or aluminum atoms in the aluminum interconnections may be diffused out to form an alloy layer containing the copper atoms and the aluminum atoms. The alloy layer may have a high resistivity, thereby degrading electrical characteristics of the semiconductor device.

Moreover, the aluminum interconnection may be formed in an opening, for example, the contact hole. As the integration density of the semiconductor devices increases, an aspect ratio of the contact hole also may increase. Accordingly, it may be difficult to completely fill the contact hole without any voids during formation of the aluminum interconnection. The void in the contact hole may lead to a degradation of the electrical characteristics of the semiconductor device.

### SUMMARY OF THE INVENTION

Exemplary embodiments of the present invention are directed to semiconductor devices having metal interconnections, semiconductor cluster tools used in fabrication thereof and methods of fabricating the same. In an exemplary embodiment, a semiconductor device comprises a semiconductor substrate including a conductive pattern. An insulating layer is disposed on the conductive pattern and the semiconductor substrate. The insulating layer has an opening which penetrates the insulating layer to expose a portion of the conductive pattern. A metal interconnection is disposed on the insulating layer and in the opening. A first diffusion barrier pattern is disposed between the metal interconnection and the conductive pattern. The first diffusion barrier pattern contains oxygen atoms.

In some embodiments, the oxygen atoms may be located in grain boundaries of the first diffusion barrier pattern.

In other embodiments, the conductive pattern may comprise copper, and the metal interconnection may comprise aluminum.

In still other embodiments, the semiconductor device may further comprise a second diffusion barrier pattern between the first diffusion barrier pattern and the metal interconnection. Each of the first and second diffusion barrier patterns may comprise refractory metal. The refractory metal may comprise at least one of titanium (Ti), tantalum (Ta), niobium (Nb), vanadium (V), zirconium (Zr), hafnium (Hf), molybdenum (Mo), rhenium (Re), tungsten (W) and titanium zirconium (TiZr). Alternatively, each of the first and second diffusion barrier patterns may comprise refractory metal nitride. In this case, the refractory metal nitride layer may comprise one of titanium nitride (TiN), tantalum nitride (TaN), niobium nitride (NbN), vanadium nitride (VN), zirconium nitride (ZrN), hafnium nitride (HfN), molybdenum nitride (MoN), rhenium nitride (ReN), tungsten nitride (WN) and titanium zirconium nitride (TiZrN). The second diffusion barrier pattern may extend onto a sidewall of the opening. In this case, the semiconductor device may further comprise a deposition resistant pattern disposed between an upper sidewall of the second diffusion barrier pattern in the opening and an upper sidewall of the metal interconnection in the opening. As a result, a lower sidewall of the second diffusion barrier pattern in the opening may be in direct contact with the metal interconnection. The second diffusion barrier pattern may comprise a first metal nitride layer, and the deposition resistant pattern may comprise a second metal nitride layer. Nitrogen content of the second metal nitride layer may be higher than that of the first metal nitride layer. The first and second metal nitride layers may comprise the same refractory metal. The second diffusion barrier pattern may comprise a refractory metal layer and the deposition resistant pattern may comprise a refractory metal nitride layer.

In another exemplary embodiment, a semiconductor cluster tool comprises a first chamber performing at least one of forming a preliminary diffusion barrier layer on a substrate having an opening, supplying oxygen atoms onto the preliminary diffusion barrier layer to form a first diffusion barrier layer, and forming a second diffusion barrier layer on the first diffusion barrier layer. A second chamber is disposed to form a deposition resistant layer on an upper sidewall of the second diffusion barrier layer in the opening and a top surface of the second diffusion barrier layer outside the opening. The deposition resistant layer exposes a lower sidewall of the second diffusion barrier layer in the opening. A third chamber is disposed to form a metal layer on the substrate having the deposition resistant layer. The metal layer fills the opening.

In some embodiments, the semiconductor cluster tool may include a fourth chamber and a fifth chamber. In this case, the forming of the preliminary diffusion barrier layer is performed in the first chamber, the supplying of oxygen atoms is performed in the fourth chamber, and the forming of a second diffusion barrier layer is performed in the fifth chamber.

In other embodiments, the fourth chamber may be one of a cleaning chamber, a degassing chamber and a cooling chamber. The cleaning chamber may be configured to clean a surface of the substrate having the opening.

In still other embodiments, the substrate may have an insulating layer, and the opening is located to penetrate the insulating layer.

In still another exemplary embodiment, a method of fabricating a semiconductor device comprises providing a semiconductor substrate having a conductive pattern. An insulating layer is formed on the conductive pattern and the semiconductor substrate. The insulating layer is patterned to form an opening which exposes a portion of the conductive pattern. A preliminary diffusion barrier layer is formed on an inner wall of the opening and a top surface of the insulating layer. Oxygen atoms are supplied onto the preliminary diffusion barrier layer to form a first diffusion barrier layer. A metal layer is formed on the first diffusion barrier layer. The metal layer is formed to fill the opening surrounded by the first diffusion barrier layer.

In some embodiments, the oxygen atoms may be supplied into grain boundaries of the preliminary diffusion barrier layer.

In other embodiments, the oxygen atoms may be supplied using a thermal oxygen treatment process.

In still other embodiments, the oxygen atoms may be supplied using an oxygen plasma process.

In yet other embodiments, the oxygen atoms may be supplied using at least one of an O₂ gas, an N₂O gas, an H₂O gas, a mixture of an O₂ gas and an H₂ gas, and an O₃ gas.

In yet still other embodiments, a second diffusion barrier layer may be additionally formed on the first diffusion barrier layer prior to formation of the metal layer. Each of the first and second diffusion barrier layers may be formed of a refractory metal layer. The refractory metal layer may comprise at least one of titanium (Ti), tantalum (Ta), niobium (Nb), vanadium (V), zirconium (Zr), hafnium (Hf), molybdenum (Mo), rhenium (Re) and tungsten (W). Alternatively, each of the first and second diffusion barrier layers is formed of a refractory metal nitride layer. The refractory metal nitride layer may comprise one of titanium nitride (TiN), tantalum nitride (TaN), niobium nitride (NbN), vanadium nitride (VN), zirconium nitride (ZrN), hafnium nitride (HfN), molybdenum nitride (MoN), rhenium nitride (ReN), tungsten nitride (WN) and titanium zirconium nitride (TiZrN).

In further embodiments, the conductive pattern may be formed of a copper layer, and the metal layer is formed of an aluminum layer.

In yet further embodiments, the method may further comprise forming a second diffusion barrier layer on the first diffusion barrier layer prior to formation of the metal layer and patterning the metal layer, the second diffusion barrier layer and the first diffusion barrier layer to form a first diffusion barrier pattern, a second diffusion barrier pattern and a metal interconnection which are sequentially stacked. In this case, the metal interconnection may be formed to fill the opening surrounded by the second diffusion barrier pattern. A deposition resistant layer may be additionally formed on the substrate having the second diffusion barrier layer prior to formation of the metal layer. The deposition resistant layer may be formed on a top surface of the second diffusion barrier layer outside the opening and an upper sidewall of the second diffusion barrier layer in the opening to expose a lower sidewall of the second diffusion barrier layer in the opening. The deposition resistant layer may be patterned during formation of the metal interconnection, thereby forming a deposition resistant pattern under the metal interconnection. The metal layer may be formed using a chemical vapor deposition (CVD) technique. In this case, a deposition rate of the metal layer on the exposed second diffusion barrier layer may be higher than that of the metal layer on the deposition resistant layer. The second diffusion barrier layer may be formed of a first metal nitride layer, and the deposition resistant layer is formed of a second metal nitride layer. Further, nitrogen content of the second metal nitride layer may be higher than that of the first metal nitride layer. The second diffusion barrier layer and the deposition resistant layer may comprise the same refractory metal. The second diffusion barrier layer may be formed of a refractory metal layer, and the deposition resistant layer may be formed of a refractory metal nitride layer. The second diffusion barrier layer may be formed using a chemical vapor deposition (CVD) technique, and the deposition resistant layer may be formed using a physical vapor deposition (PVD) technique. The conductive pattern, the preliminary diffusion barrier layer, the first diffusion barrier layer, the second diffusion barrier layer, the deposition resistant layer and the metal layer may be formed using a single cluster tool.

### BRIEF DESCRIPTION OF THE DRAWINGS

FIGS. 1 to 8 are cross sectional views illustrating methods of fabricating semiconductor devices according to embodiments of the present invention and semiconductor devices fabricated thereby.

FIGS. 9 to 11 are graphs showing some characteristics of semiconductor devices according to embodiments of the present invention.

FIG. 12 is a schematic view illustrating a semiconductor cluster tool used in fabrication of a semiconductor device according to an embodiment of the present invention.

### DETAILED DESCRIPTION OF PREFERRED EMBODIMENTS

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly. Moreover, the term “beneath” indicates a relationship of one layer or region to another layer or region relative to the substrate, as illustrated in the figures.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to plan and cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

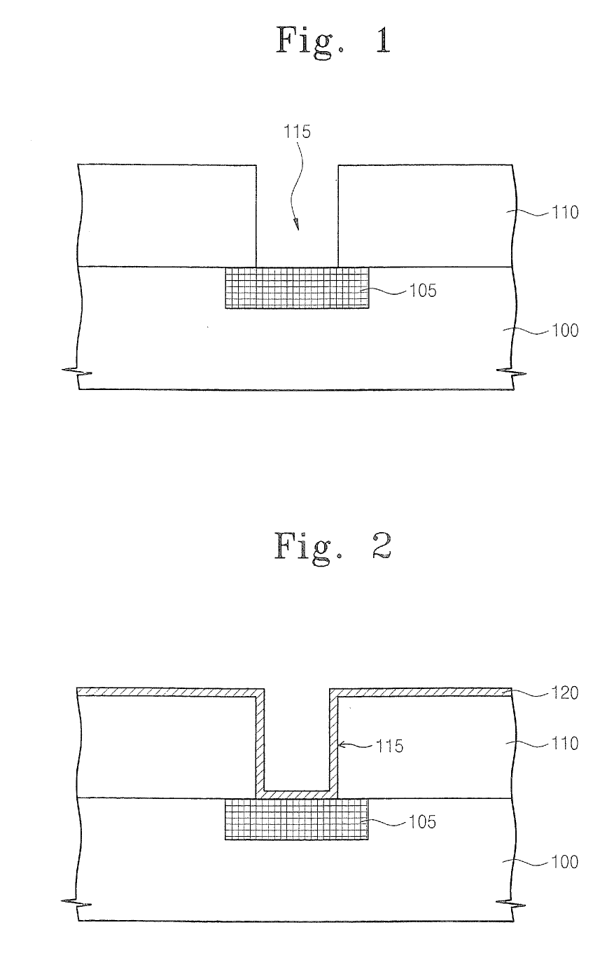

FIGS. 1 to 8 are cross sectional views illustrating methods of fabricating semiconductor devices according to embodiments of the present invention and semiconductor devices fabricated thereby.

Referring to FIG. 1, a semiconductor substrate 100 having a conductive pattern 105 is provided. The conductive pattern 105 may comprise copper (Cu). That is, the conductive pattern 105 may be formed of a copper layer. An insulating layer 110 may be formed on the conductive pattern 105 and the semiconductor substrate 100. The insulating layer 1 10 may be formed of a silicon oxide layer using a chemical vapor deposition (CVD) technique. The insulating layer 110 is patterned to form an opening 115 which exposes a portion of the conductive pattern 105. The opening 115 may be formed to have a hole-shaped configuration or a line-shaped configuration.

Referring to FIG. 2, a preliminary diffusion barrier layer 120 is formed on an inner wall of the opening 115 and a top surface of the insulating layer 110. The inner wall of the opening 115 includes a sidewall of the opening 115 and the exposed surface of the conductive pattern 105 by the opening 115. The preliminary diffusion barrier layer 120 may be formed using a CVD technique, thereby having a surface profile which is substantially consistent with that of the substrate including the insulating layer 110 and the opening 115, as shown in FIG. 2. The preliminary diffusion barrier layer 120 may be formed of a refractory metal layer. For example, the preliminary diffusion barrier layer 120 may be formed of at least one of a titanium (Ti) layer, a tantalum (Ta) layer, a niobium (Nb) layer, a vanadium (V) layer, a zirconium (Zr) layer, a hafnium (Hf) layer, a molybdenum (Mo) layer, a rhenium (Re) layer, a tungsten (W) layer and a titanium zirconium (TiZr) layer. Alternatively, the preliminary diffusion barrier layer 120 may be formed of a refractory metal nitride layer. For example, the preliminary diffusion barrier layer 120 may be formed of at least one of a titanium nitride (TiN) layer, a tantalum nitride (TaN) layer, a niobium nitride (NbN) layer, a vanadium nitride (VN) layer, a zirconium nitride (ZrN) layer, a hafnium nitride (HfN) layer, a molybdenum nitride (MoN) layer, a rhenium nitride (ReN) layer, a tungsten nitride (WN) layer and a titanium zirconium nitride (TiZrN) layer.

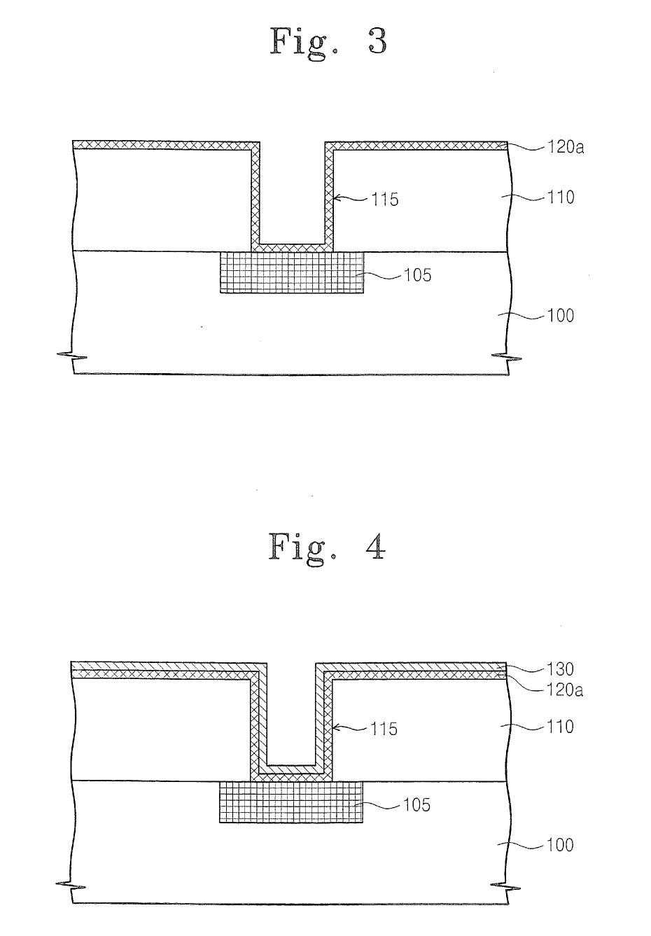

Referring to FIG. 3, oxygen atoms are supplied onto the preliminary diffusion barrier layer 120 to form a first diffusion barrier layer 120a. The oxygen atoms may react on the preliminary diffusion barrier layer 120 to oxidize grains of the preliminary diffusion barrier layer 120 or to fill grain boundaries of the preliminary diffusion barrier layer 120. The oxygen atoms may be supplied using an oxygen-based gas. The oxygen-based gas may comprise at least one of an O₂ gas, an N₂O gas, an H₂O gas, a mixture of an O₂ gas and an H₂ gas, and an O₃ gas.

Alternatively, the oxygen atoms may be supplied using an oxygen treatment process. The oxygen treatment process may comprise a thermal treatment process which is performed with an oxygen gas at a high temperature. For example, the oxygen treatment process may be performed under a process condition having a temperature of about 20° C. to 600° C., an oxygen gas flow rate of about 1 to 10000 standard cubic centimeter per minute (sccm), and a pressure of greater than about 0 torr and less than or equal to about 1000 torr. In another embodiment, the oxygen atoms may be supplied using an oxygen plasma process. For example, the oxygen plasma process may be performed with oxygen radicals and oxygen ions under a process condition having a temperature of about 20° C. to 600° C., an oxygen gas flow rate of about 1 to 10000 sccm, an inert gas flow rate of about 1 to 10000 sccm, and a pressure of greater than about 0 torr and less than or equal to about 1000 torr.

Referring to FIG. 4, a second diffusion barrier layer 130 may be formed on the first diffusion barrier layer 120a. The second diffusion barrier layer 130 may be formed using a CVD technique, thereby having a surface profile which is substantially consistent with that of the first diffusion barrier layer 120a, as shown in FIG. 4. The second diffusion barrier layer 130 may be formed of a refractory metal layer. For example, the second diffusion barrier layer 130 may be formed of at least one of titanium (Ti), tantalum (Ta), niobium (Nb), vanadium (V), zirconium (Zr), hafnium (Hf), molybdenum (Mo), rhenium (Re), tungsten (W) and titanium zirconium (TiZr). Alternatively, the second diffusion barrier layer 130 may be formed of a refractory metal nitride layer. For example, the second diffusion barrier layer 130 may be formed of at least one of titanium nitride (TiN), tantalum nitride (TaN), niobium nitride (NbN), vanadium nitride (VN), zirconium nitride (ZrN), hafnium nitride (HfN), molybdenum nitride (MoN), rhenium nitride (ReN), tungsten nitride (WN) and titanium zirconium nitride (TiZrN).

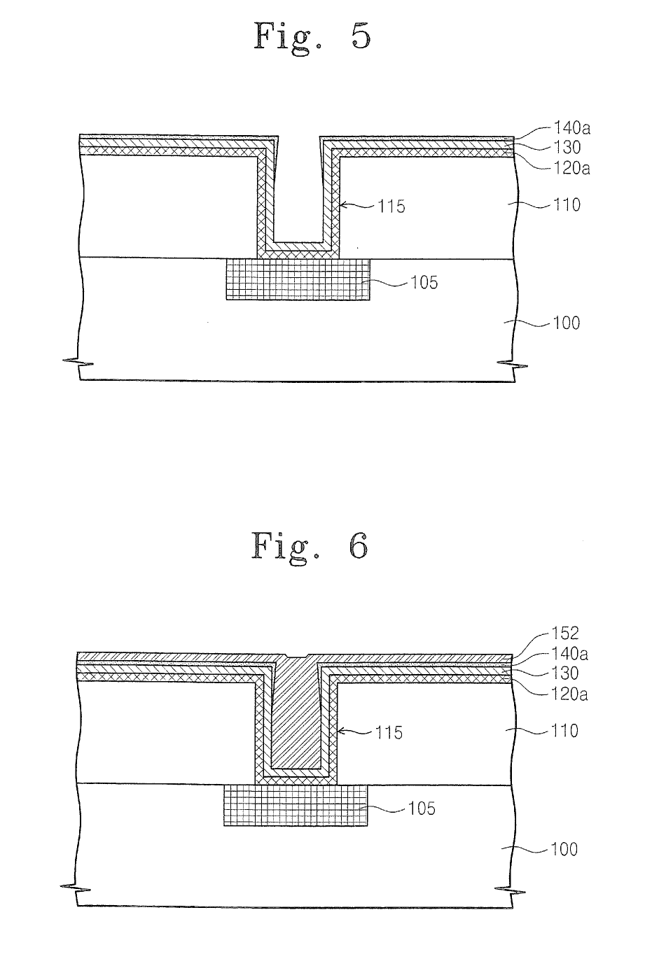

Referring to FIG. 5, a deposition resistant layer 140a may be formed on the second diffusion barrier layer 130. In the illustrated embodiment, the deposition resistant layer 140a may be formed using a deposition process which exhibits poor step coverage. Accordingly, the deposition resistant layer 140a may be formed on an upper sidewall of the second diffusion barrier layer 130 in the opening 115 and on a top surface of the second diffusion barrier layer 130 outside the opening 115. In addition, the deposition resistant layer 140a may be formed on a top surface of the second diffusion barrier layer 130 over a bottom surface of the opening 115. As a result, the deposition resistant layer 140a may be formed to have an overhang which covers an upper corner of the opening 115, as illustrated. Further, the deposition resistant layer 140a may be formed to expose a lower sidewall of the second diffusion barrier layer 130 in the opening 115, as illustrated. The deposition resistant layer 140a may be formed of a refractory metal nitride layer using a physical vapor deposition (PVD) technique. For example, the deposition resistant layer 140a may be formed using a sputtering technique. In this case, a nitrogen gas may be used in formation of the deposition resistant layer 140a.

The second diffusion barrier layer 130 may be formed of a first metal nitride layer, and the deposition resistant layer 140a may be formed of a second metal nitride layer. In this case, nitrogen content of the second metal nitride may be greater than that of the first metal nitride layer. The refractory metal contained in the deposition resistant layer 140a may be the same material as the refractory metal contained in the second diffusion barrier layer 130. When the second diffusion barrier layer 130 is formed of a refractory metal layer, the deposition resistant layer 140a may be formed of a refractory metal nitride layer.

Referring to FIG. 6, a first metal layer 152 may be formed on the substrate including the deposition resistant layer 140a. The first metal layer 152 may be formed using a CVD technique. The first metal layer 152 may comprise aluminum. When the first metal layer 152 is formed using the CVD technique, the first metal layer 152 may be deposited at a first deposition rate on the second diffusion barrier layer 130 which is exposed inside the opening 115 and at a second deposition rate on the deposition resistant layer 140a. In this case, the first deposition rate may be higher than second deposition rate. This is because the nitrogen content of the second diffusion barrier layer 130 is less than that of the deposition resistant layer 140a. Accordingly, the first metal layer 152 may be formed to completely fill the opening 115 without any voids.

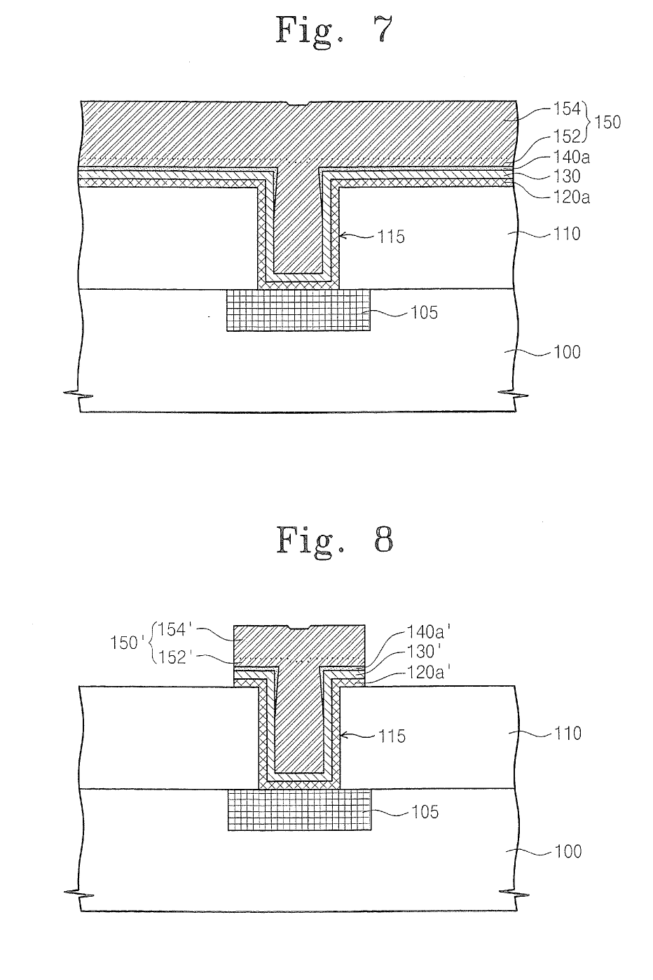

Referring to FIG. 7, a second metal layer 154 is formed on the first metal layer 152. The second metal layer 154 may be formed using a PVD technique to reduce a deposition time thereof. When the second metal layer 154 is deposited at a low temperature, a reflow process may be performed after deposition of the second metal layer 154. Alternatively, when the second metal layer 154 is deposited at a high temperature, the reflow process may be omitted. The first and second metal layers 152 and 154 constitute a metal layer 150.

The conductive pattern 105, the preliminary diffusion barrier layer 120, the first diffusion barrier layer 120a, the second diffusion barrier layer 130, the deposition resistant layer 140a and the metal layer 150 may be formed using a single cluster tool.

According to the embodiments described above, the first and second diffusion barrier layers 120a and 130 may prevent or inhibit the copper atoms in the conductive pattern 105 from being diffused into the metal layer 150 and/or the aluminum atoms in the metal layer 150 from being diffused into the conductive pattern 105. That is, one of the first and second diffusion barrier layers 120a and 130 may serve to block copper diffusion, and the other layer may serve to block aluminum diffusion. In more detail, since grain boundaries of the first diffusion barrier layer 120a are stuffed with oxygen atoms, the aluminum atoms in the metal layer 150 may react on the oxygen atoms to form aluminum oxide at the grain boundaries. The aluminum oxide may block diffusion paths of the aluminum atoms.

Referring to FIG. 8, the metal layer 150, the deposition resistant layer 140a, the second diffusion barrier layer 130 and the first diffusion barrier layer 120a may be patterned to form a first diffusion barrier pattern 120a′, a second diffusion barrier pattern 130′, a deposition resistant pattern 140a′ and a metal interconnection 150′ which are sequentially stacked. The metal interconnection 150′ may comprise a first metal pattern 152′ and a second metal pattern 154′ which are sequentially stacked. The metal interconnection 150′ may be formed to cover the opening 115.

Now, semiconductor devices according to embodiments of the present invention will be described with reference to FIG. 8.

Referring again to FIG. 8, a semiconductor substrate 100 having a conductive pattern 105 is provided. The conductive pattern 105 may comprise copper. That is, the conductive pattern 105 may be a copper line. An interlayer insulating layer 110 may be disposed on the conductive pattern 105 and the semiconductor substrate 100. A portion of the conductive pattern 105 may be exposed by an opening 115 which penetrates the interlayer insulating layer 110. A metal interconnection 150′ is disposed on the interlayer insulating layer 110 and in the opening 115. The metal interconnection 150′ may comprise a first metal pattern 152′ and a second metal pattern 154′ which are sequentially stacked. The first metal pattern 152′ may be formed using a CVD technique to fill the opening 115, and the second metal pattern 154′ may be formed using a PVD technique. The metal interconnection 150′ may comprise aluminum and may have a cylinder-shaped shaped configuration or a line-shaped configuration.

A first diffusion barrier pattern 120a′ may be disposed between the metal interconnection 150′ and the conductive pattern 105. The first diffusion barrier pattern 120a′ may extend onto a sidewall of the opening 115 and a top surface of the interlayer insulating layer 110. That is, the first diffusion barrier pattern 120a′ may be disposed between the metal interconnection 150′ and the interlayer insulating layer 110. The first diffusion barrier pattern 120a′ may comprise oxygen. For example, the first diffusion barrier pattern 120a′ may have grain boundaries which are stuffed with oxygen atoms. A second diffusion barrier pattern 130′ may be disposed between the first diffusion barrier pattern 120a′ and the metal interconnection 150′.

Each of the first and second diffusion barrier patterns 120a′ and 130′ may comprise refractory metal. For example, each of the first and second diffusion barrier patterns 120a′ and 130′ may comprise at least one of titanium (Ti), tantalum (Ta), niobium (Nb), vanadium (V), zirconium (Zr), hafnium (Hf), molybdenum (Mo), rhenium (Re), tungsten (W) and titanium zirconium (TiZr). Alternatively, each of the first and second diffusion barrier patterns 120a′ and 130′ may comprise refractory metal nitride. For example, each of the first and second diffusion barrier patterns 120a′ and 130′ may comprise at least ones of titanium nitride (TiN), tantalum nitride (TaN), niobium nitride (NbN), vanadium nitride (VN), zirconium nitride (ZrN), hafnium nitride (HfN), molybdenum nitride (MoN), rhenium nitride (ReN), tungsten nitride (WN) and titanium zirconium nitride (TiZrN).

The first and second diffusion barrier patterns 120a′ and 130′ may prevent copper atoms in the conductive pattern 105 from being diffused into the metal interconnection 150′ or aluminum atoms in the metal interconnection 150′ from being diffused into the conductive pattern 105. This is because the grain boundaries of the first diffusion barrier pattern 120a′ are stuffed with oxygen atoms. That is, if the aluminum atoms in the metal interconnection 150′ reach the first diffusion barrier pattern 120a′, the aluminum atoms may react on the oxygen atoms in the metal interconnection 150′ to form aluminum oxide. The aluminum oxide material may serve to block diffusion paths of the aluminum atoms.

A deposition resistant pattern 140a′ may be disposed at a portion of an interface between the second diffusion barrier pattern 130′ and the metal interconnection 150′. For example, the deposition resistant pattern 140a′ may be disposed between a top surface of the second diffusion barrier pattern 130′ over the interlayer insulating layer 110 and an edge of the metal interconnection 150′. Further, the deposition resistant pattern 140a′ may extend to cover an upper sidewall of the second diffusion barrier pattern 130′ in the opening 115. In addition, the deposition resistant pattern 140a′ may be disposed between a top surface of the second diffusion barrier pattern 130′ over a bottom surface of the opening 115 and the metal interconnection 150′ in the opening 115. As a result, the metal interconnection 150′ may be in direct contact with a lower sidewall of the second diffusion barrier pattern 130′ in the opening 115. The deposition resistant layer 140a may comprise a refractory metal nitride layer.

The second diffusion barrier pattern 130′ may comprise a first metal nitride layer, and the deposition resistant pattern 140a′ may comprise a second metal nitride layer. In this case, nitrogen content of the second metal nitride may be greater than that of the first metal nitride layer. The refractory metal contained in the deposition resistant pattern 140a′ may be the same material as the refractory metal contained in the second diffusion barrier pattern 130′. When the second diffusion barrier pattern 130′ comprises a refractory metal layer, the deposition resistant pattern 140a′ may comprise a refractory metal nitride layer.

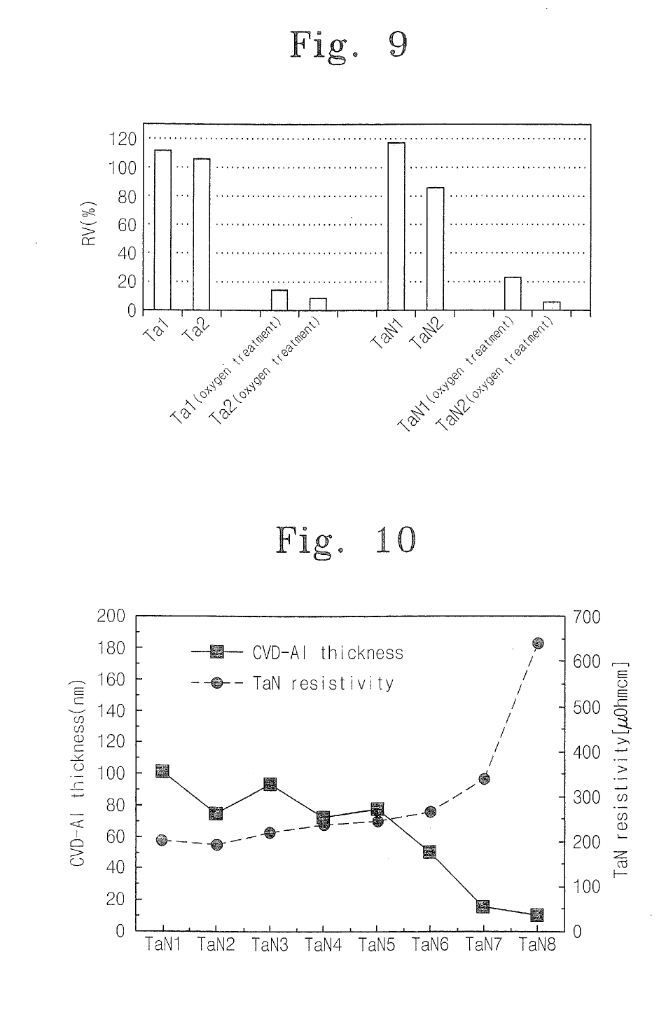

FIG. 9 is a graph showing sheet resistance variations of various metal layers fabricated according to the conventional arts and the present invention. In FIG. 9, the abscissa represents the conventional metal layers and the metal layers fabricated according to the present invention, and the ordinate represents a sheet resistance variation RV between a first sheet resistance RS1 of the metal layer before an annealing process and a second sheet resistance RS2 of the metal layer after the annealing process. The conventional metal layers are indicated by “Ta1”, “Ta2”, “TaN1” and “TaN2” on the abscissa, and the metal layers according to the present invention are indicated by “Ta1 (oxygen treatment)”, “Ta2 (oxygen treatment)”, “TaN1 (oxygen treatment)” and “TaN2 (oxygen treatment)” on the abscissa. Each of the metal layers was fabricated by the steps of forming a copper layer on a semiconductor substrate, forming a diffusion barrier layer on the copper layer, forming an aluminum layer on the diffusion barrier layer, and annealing the copper layer, the diffusion barrier layer and the aluminum layer. In this case, the first sheet resistance RS1 was measured prior to the annealing process, and the second sheet resistance RS2 was measured after the annealing process. Accordingly, the sheet resistance variation RV was calculated using the following equation.

RV={(RS2−RS1)×100}÷RS1

In the conventional art, The diffusion barrier layer was formed of a first tantalum layer having a thickness of 50 angstroms (see “Ta1”), a second tantalum layer having a thickness of 100 angstroms (see “Ta2”), a first tantalum nitride layer having a thickness of 50 angstroms (see “TaN1”), or a second tantalum nitride layer (see “TaN2”). On the contrary, the diffusion barrier layer according to the present invention was formed using an oxygen stuffing process after formation of a preliminary diffusion barrier layer (see “Ta1 (oxygen treatment)”, “Ta2 (oxygen treatment)”, “TaN1 (oxygen treatment)”, or “TaN2 (oxygen treatment)”). In this case, the preliminary diffusion barrier layer corresponds to one of the conventional diffusion barrier layers.

Referring to FIG. 9, the conventional metal layers Ta1, Ta2, TaN1 and TaN2 exhibited the sheet resistance variation RV of about 80% to 120%. In contrast, the metal layers according to the present invention exhibited the sheet resistance variation RV of about 5% to 25%. This may be understood that alloy layers containing copper and aluminum are formed in the conventional metal layers during the annealing process to significantly increase the sheet resistance.

FIG. 10 is a graph illustrating physical and electrical parameters of metal layers according to tantalum nitride layers having different nitrogen contents. In FIG. 10, the abscissa represents various tantalum nitride layers TaN1, TaN2, . . . , and TaN8 having different nitrogen contents, the left side ordinate represents thickness of CVD aluminum layers deposited on the tantalum nitride layers, and the right side ordinate represents resistivity of the respective tantalum nitride layers. The tantalum nitride layers TaN1, TaN2, . . . , and TaN8 were formed using a nitrogen reactive sputtering technique, and the CVD aluminum layers were formed on the tantalum nitride layers, respectively. The CVD aluminum layers were deposited during the same deposition time. The nitrogen content of the tantalum nitride layers gradually increases toward the right ordinate. That is, the eighth tantalum nitride layer TaN8 was formed to have maximum nitrogen content, and the first tantalum nitride layer TaN1 was formed to have minimum nitrogen content.

As can be seen from FIG. 10, the higher the nitrogen content of the tantalum nitride layer is, the lower the deposition rate of the CVD aluminum layer on the tantalum nitride layer is. Accordingly, when the tantalum nitride layer is used as the second diffusion barrier layer 130 and the deposition resistant layer 140a described with reference to FIGS. 4 and 5, it is preferable that the nitrogen content of the second diffusion barrier layer 130 is lower than that of the deposition resistant layer 140a in order to completely fill the opening without any voids.

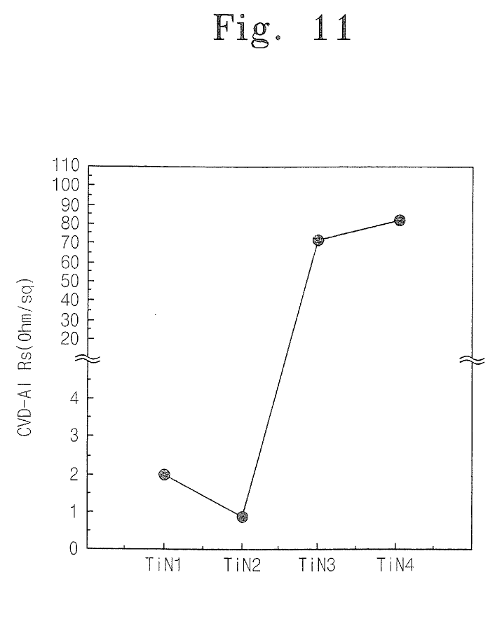

FIG. 11 is a graph illustrating sheet resistance of CVD aluminum layers deposited on various titanium nitride layers having different nitrogen content. In FIG. 11, the abscissa represents various titanium nitride layers TiN1, TiN2, TiN3 and TiN4 having different nitrogen contents, and the ordinate represents sheet resistance of CVD aluminum layers deposited on the titanium nitride layers TiN1, TiN2, TiN3 and TiN4. The titanium nitride layers TiN1, TiN2, TiN3 and TiN4 were formed using a nitrogen reactive sputtering technique. The CVD aluminum layers were deposited during the same deposition time. The nitrogen content of the titanium nitride layers gradually increases toward the right ordinate. That is, the fourth titanium nitride layer TiN4 was formed to have maximum nitrogen content, and the first titanium nitride layer TiN1 was formed to have minimum nitrogen content.

As can be seen from FIG. 11, the higher the nitrogen content of the titanium nitride layer is, the higher the sheet resistance of the CVD aluminum layer on the titanium nitride layer is. This may be understood that the thickness of the CVD aluminum layer deposited on the titanium nitride layer is inversely proportional to the nitrogen content of the titanium nitride layer.

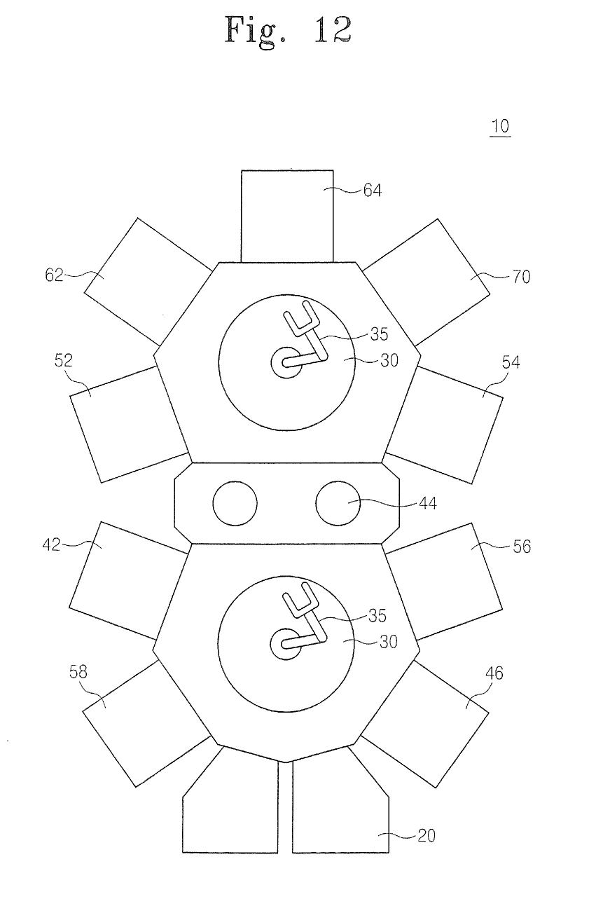

FIG. 12 is a schematic view illustrating a semiconductor cluster tool used in fabrication of a semiconductor device according to an embodiment of the present invention.

Referring to FIG. 12, a semiconductor cluster tool 10 may comprise first and second load lock chambers 20, first and second transfer chambers 30, first and second cooling chambers 44 and a plurality of process chambers. The first and second load lock chambers 20 may be attached to the first transfer chamber 30, and the first and second cooling chambers 44 may be disposed in parallel between the first and second transfer chambers 30. The process chambers may include a cleaning chamber 42, a degassing chamber 46 and first to seventh chambers 52, 54, 56, 58, 62, 64 and 70. The cleaning chamber 42, the degassing chamber 46, the third chamber 56 and the fourth chamber 58 are attached to the first transfer chamber 30, and the first chamber 52, the second chamber 54, the fifth to seventh chambers 62, 64 and 70 are attached to the second transfer chamber 30.

Each of the transfer chambers 30 may include a wafer transferring unit for moving a wafer, and the wafer transferring unit may have a robot arm 35 on which the wafer is located. The robot arm 35 may move the wafer located in the transfer chamber 30 into one of the chambers attached to the transfer chamber 30. Further, the robot arm 35 may move the wafer located in one of the chambers attached to the transfer chamber 30 into the transfer chamber 30.

Now, methods of fabricating a semiconductor device using the semiconductor cluster tool 10 will be described.

Referring again to FIGS. 1 to 7 and FIG. 12, a wafer may be fabricated to have an opening 115 such as a contact hole or a line-shaped groove. The wafer having the opening 115 may be loaded into one of the load lock chambers 20. The wafer in the load lock chamber 20 may be transferred into the cleaning chamber 42 through the first transfer chamber 30. The wafer having the opening 115 may be cleaned using an argon (Ar) gas and/or a helium (He) gas in the cleaning chamber 42. The cleaned wafer may be transferred into the first chamber 52 through the first and second transfer chambers 30 and one of the cooling chamber 44, and a preliminary diffusion barrier layer 120 may be formed on the cleaned wafer in the first chamber 52. Subsequently, oxygen atoms may be supplied into the first chamber 52 to form a first diffusion barrier layer 120a. Alternatively, the oxygen atoms may be supplied into the second chamber 54 after the wafer having the preliminary diffusion barrier layer is transferred into the second chamber 54. That is, the first diffusion barrier layer 120a may be formed in the first chamber 52 or the second chamber 54.

The wafer having the first diffusion barrier layer 120a may be moved into the third chamber 56 through the first and second transfer chambers 30 and one of the cooling chamber 44. A second diffusion barrier layer 130 may be formed on the first diffusion barrier layer 120a in the third chamber 56. Alternatively, the second diffusion barrier layer 130 may be formed in the first chamber 52. That is, the preliminary diffusion barrier layer 120, the first diffusion barrier layer 120a and the second diffusion barrier layer 130 may be formed in the same chamber in which the oxygen atoms can be supplied.

The wafer having the second diffusion barrier layer 130 may be transferred into the fourth chamber 58 attached to the first transfer chamber 130, and a deposition resistant layer 140a may be formed on the wafer having the second diffusion barrier layer 130. In this case, the fourth chamber 58 may be a PVD chamber which exhibits poor step coverage. Thus, the deposition resistant layer 140a may be formed on an upper sidewall of the second diffusion barrier layer 130 in the opening 115 and a top surface of the second diffusion barrier layer 130 outside of the opening 115. Therefore, a lower sidewall of the second diffusion barrier layer 130 in the opening 115 may be still exposed even after formation of the deposition resistant layer 140a.

The wafer having the deposition resistant layer 140a may be transferred into the fifth chamber 62, and a first metal layer 152, for example, an aluminum layer may be formed on the deposition resistant layer 140a and in the opening 115. The fifth chamber 62 may be a CVD chamber. The wafer having the first metal layer 152 may be transferred into the sixth chamber 64, and a second metal layer 154 may be formed on the first metal layer 152. The sixth chamber 64 may be a PVD chamber.

The wafer may further comprise a conductive pattern 105. The conductive pattern 105 may be formed in the seventh chamber 70 prior to formation of the opening 115. In other embodiments, the oxygen atoms for forming the first diffusion barrier layer 120a may be supplied into the degassing chamber 46 or the cooling chamber 44.

According to the embodiments described above, a diffusion barrier layer may be formed of a combination layer, and grain boundaries of the diffusion layer may be stuffed with oxygen atoms. Thus, the diffusion barrier layer having the stuffed oxygen atoms may act as a blocking layer of copper diffusion and/or aluminum diffusion. In addition, a deposition resistant layer may be formed on the diffusion barrier layer using a PVD technique which exhibits poor step coverage, and the deposition resistant layer may have a nitrogen content which is higher than that of the diffusion barrier layer. As a result, when an aluminum layer is formed on the deposition resistant layer outside an opening and the diffusion barrier layer inside the opening, the aluminum layer may completely fill the opening without any voids.

Although the present invention has been described in connection with the embodiments of the present invention illustrated in the accompanying drawings, it is not limited thereto. It will be apparent to those skilled in the art that various substitutions, modifications and changes may be made without departing from the scope and spirit of the invention.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of fabricating a semiconductor device, comprising:
providing a semiconductor substrate having a conductive pattern;
forming an insulating layer on the conductive pattern and the semiconductor substrate;
patterning the insulating layer to form an opening which exposes a portion of the conductive pattern;
forming a preliminary diffusion barrier layer on an inner wall of the opening and a top surface of the insulating layer;
supplying oxygen atoms onto the preliminary diffusion barrier layer to form a first diffusion barrier layer; and
forming a metal layer on the first diffusion barrier layer,
wherein the metal layer is formed to fill the opening surrounded by the first diffusion barrier layer.

2. The method as set forth in claim 1, wherein the oxygen atoms are supplied into grain boundaries of the preliminary diffusion barrier layer.

3. The method as set forth in claim 1, wherein the oxygen atoms are supplied using a thermal oxygen treatment process.

4. The method as set forth in claim 1, wherein the oxygen atoms are supplied using an oxygen plasma process.

5. The method as set forth in claim 1, wherein the oxygen atoms are supplied using at least one of an O₂ gas, an N₂O gas, an H₂O gas, a mixture of an O₂ gas and an H₂ gas, and an O₃ gas.

6. The method as set forth in claim 1, further comprising forming a second diffusion barrier layer on the first diffusion barrier layer prior to formation of the metal layer.

7. The method as set forth in claim 6, wherein each of the first and second diffusion barrier layers is formed of a refractory metal layer.

8. The method as set forth in claim 7, wherein the refractory metal layer comprises at least one of a titanium (Ti), a tantalum (Ta), a niobium (Nb), a vanadium (V), a zirconium (Zr), a hafnium (Hf), a molybdenum (Mo), a rhenium (Re) and a tungsten (W).

9. The method as set forth in claim 7, wherein the refractory metal layer comprises a titanium-zirconium (TiZr).

10. The method as set forth in claim 6, wherein each of the first and second diffusion barrier layers is formed of a refractory metal nitride layer.

11. The method as set forth in claim 10, wherein the refractory metal nitride layer comprises one of a titanium nitride (TiN), a tantalum nitride (TaN), a niobium nitride (NbN), a vanadium nitride (VN), a zirconium nitride (ZrN), a hafnium nitride (HfN), a molybdenum nitride (MoN), a rhenium nitride (ReN) and a tungsten nitride (WN).

12. The method as set forth in claim 10, wherein the refractory metal nitride layer comprises a titanium-zirconium-nitride (TiZrN).

13. The method as set forth in claim 1, wherein the conductive pattern comprises copper and the metal layer comprises aluminum.

14. The method as set forth in claim 6, further comprising:
patterning the metal layer, the second diffusion barrier layer and the first diffusion barrier layer to form a first diffusion barrier pattern, a second diffusion barrier pattern and a metal interconnection which are sequentially stacked, the metal interconnection is formed to fill the opening surrounded by the second diffusion barrier pattern.

15. The method as set forth in claim 14, further comprising forming a deposition resistant layer on the substrate having the second diffusion barrier layer prior to formation of the metal layer,
wherein the deposition resistant layer is formed on a top surface of the second diffusion barrier layer outside the opening and an upper sidewall of the second diffusion barrier layer in the opening to expose a lower sidewall of the second diffusion barrier layer in the opening,
and wherein the deposition resistant layer is patterned during formation of the metal interconnection, thereby forming a deposition resistant pattern under the metal interconnection.

16. The method as set forth in claim 15, wherein the metal layer is formed using a chemical vapor deposition (CVD) technique, and
wherein a deposition rate of the metal layer on the exposed second diffusion barrier layer is higher than that of the metal layer on the deposition resistant layer.

17. The method as set forth in claim 16, wherein the second diffusion barrier layer is formed of a first metal nitride layer and the deposition resistant layer is formed of a second metal nitride layer,
and wherein nitrogen content of the second metal nitride layer is higher than that of the first metal nitride layer.

18. The method as set forth in claim 17, wherein the second diffusion barrier layer and the deposition resistant layer comprise the same refractory metal.

19. The method as set forth in claim 16, wherein the second diffusion barrier layer is formed of a refractory metal layer and the deposition resistant layer is formed of a refractory metal nitride layer.

20. The method as set forth in claim 15, wherein the second diffusion barrier layer is formed using a chemical vapor deposition (CVD) technique and the deposition resistant layer is formed using a physical vapor deposition (PVD) technique.

21. The method as set forth in claim 15, wherein the conductive pattern, the preliminary diffusion barrier layer, the first diffusion barrier layer, the second diffusion barrier layer, the deposition resistant layer and the metal layer are formed using a single cluster tool.

22. A semiconductor device comprising:
a semiconductor substrate including a conductive pattern;
an insulating layer on the conductive pattern and the semiconductor substrate, the insulating layer having an opening which penetrates the insulating layer to expose a portion of the conductive pattern;
a metal interconnection filling the opening; and
a first diffusion barrier pattern disposed between the metal interconnection and the conductive pattern,
wherein the first diffusion barrier pattern contains oxygen atoms.

23. A semiconductor cluster tool, comprising:
a first chamber configured to form a preliminary diffusion barrier layer on a substrate having an opening, to supply oxygen atoms onto the preliminary diffusion barrier layer to form a first diffusion barrier layer, and/or to form a second diffusion barrier layer on the first diffusion barrier layer;
a second chamber configured to form a deposition resistant layer on an upper sidewall of the second diffusion barrier layer in the opening and a top surface of the second diffusion barrier layer outside the opening, thereby exposing a lower sidewall of the second diffusion barrier layer in the opening; and
a third chamber configured to form a metal layer on the substrate having the deposition resistant layer to fill the opening.
